(19) United States
(12) Patent Application Publication
(10) Pub. No.: US 2023/0158920 A1
(43) Pub. Date: May 25, 2023

(54) METHOD FOR OPERATING A VEHICLE ELECTRICAL SYSTEM

(71) Applicants: Robert Bosch GmbH, Stuttgart (DE); Audi AG, Ingolstadt (DE)

(72) Inventors: Juergen Motz, Steinheim An Der Murr (DE); Nils Draese, Stuttgart (DE); Oliver Dieter Koller, Weinstadt (DE); Patrick Van Bergen, Korntal-Muenchingen (DE); Sebastian Kaspar, Ingolstadt (DE); Frederic Heidinger, Esslingen (DE); Marco Blach, Renningen (DE); Markus Woerz, Leonberg (DE); Martin Schneider, Grossmehring (DE)

(21) Appl. No.: 17/908,668

(22) PCT Filed: Mar. 3, 2021
(86) PCT No.: PCT/EP2021/055367

§ 371 Date: Sep. 1, 2022

(30) Foreign Application Priority Data
Mar. 5, 2020 (DE) 10 2020 105 909.4

(51) Int. Cl. B60L 58/10; B60R 16/033; G01R 31/389; G01R 31/367

(52) U.S. Cl. CPC B60L 58/10; B60R 16/033; G01R 31/389; G01R 31/367; B60L 2240/547

(57) ABSTRACT

A method for operating a vehicle electrical system, which includes an energy store. The energy store is assigned a sensor processing unit, and an electronic load distributor. At least one measured variable is detected using the sensor processing unit, and a parameter of the energy store is calculated taking the at least one measured variable into account. A plausibility check of the at least one measured variable is carried out, and a plausibility check of the calculation is carried out, for which purpose the electronic load distributor is used.

### FIELD

The present invention relates to a method for operating a vehicle electrical system and to such a vehicle electrical system.

### BACKGROUND INFORMATION

A vehicle electrical system in automotive applications is understood to mean the entirety of all electrical components in a motor vehicle. Thus, this includes both electrical consumers as well as supply sources such as, for example, batteries. A distinction is made in this case between the vehicle electrical power system and the vehicle communication system, the vehicle electrical power system above all being addressed herein, which is responsible for supplying the components of the motor vehicle with power. To control the vehicle electrical system, a microcontroller is usually provided which, in addition to control functions, also carries out monitoring functions.

In a motor vehicle, it should be noted that electrical power is available so that the motor vehicle is able to be started at any time and a sufficient power supply is provided during the operation. Even in the switched off state, however, electrical consumers should still be operable for a reasonable period of time without a subsequent start being affected.

The increasing electrification of aggregates and the introduction of new vehicle functions such as, for example, semi-automated, highly-automated or fully automated driving, increases the demand for reliability of the electrical power supply in the motor vehicle. At the same time, it should be noted, in particular, that the number of power-electronic systems is constantly growing. If one of these systems is faulty or even fails, it may result in the vehicle electrical system voltage falling outside the normal operating range, which may have a negative impact on the comfort and on the safety of the vehicle occupants.

Exemplary new driving functions are automated and autonomous driving. During the automated and autonomous driving operation in the motor vehicle, the driver is no longer available as a sensory, control-related, mechanical and energetic fall-back level. The vehicle must independently recognize its surroundings, plan, select and implement trajectories by activating the actuators. By eliminating the driver, the vehicle, i.e., the manufacturer, has the responsibility for the vehicle behavior.

### SUMMARY

Against this background, a method and a vehicle electrical system are provided by the present invention. Specific example embodiments of the present invention are disclosed herein.

A method proved according to the present invention is used to operate a vehicle electrical system, which includes an energy store, for example, a battery, the energy store being assigned a sensor processing unit, and an electronic power distributor or load distributor, at least one measured variable of the energy store being detected using the sensor processing unit and a parameter of the energy store being calculated taking this at least one measured variable into account. In a first step, a plausibility check of the at least one measured variable is carried out. In a second step, a plausibility check of the calculation takes place. The electronic load distributor is used for this purpose.

According to an example embodiment of the present invention, it may be provided that the plausibility check of the at least one measured variable in the first step is carried out once per driving cycle and the plausibility check of the calculation in the second step is carried out multiple times during the driving cycle.

According an example embodiment of the present invention, The method provides a monitoring of the capacity of the battery with ASIL C by using an electronic battery sensor (EBS) as a sensor processing unit and an intelligent electronic power distributor or load distributor. An EBS provides information about the battery condition, if necessary, taking ageing effects into account. The power distributor has the task of forwarding electrical energy to components in the vehicle electrical system. It should further be noted that an electronic battery sensor (EBS) potentially does not achieve a required systematic safety integrity, for example, ASIL C, or the hardware metrics placed on it. A plausibility check of the EBS by a power distributor represents one possibility for solving this problem.

The method provided according to the present invention has, at least in some of the embodiments, a number of advantages:

enabling a single-channel ASIL C vehicle electric power system with no additional 12V battery,
no additional measures are required in the vehicle electric power system, since an intelligent power distributor must be integrated regardless due to further functions such as, for example, separation of consumers having non-safety-relevant functions, etc., or safety measures that fulfill the same function.

Further advantages and embodiments of the present invention result from the description and from the figures.

It is understood that the features cited above and those to be explained below are applicable not only in each specified combination, but also in other combinations or alone, without departing from the scope of the present invention.

### BRIEF DESCRIPTION OF THE DRAWINGS

FIG. 1 shows a vehicle electrical system according to the related art.

FIG. 2 shows one embodiment of the presented vehicle electrical system, according to the present invention.

FIG. 3 shows an exemplary embodiment of the described method, according to the present invention.

FIG. 4 shows in a flowchart one possible plausibility check of EBS measured variables, according the present invention.

FIG. 5 shows a detail of a vehicle electrical system for illustrating the plausibility check of measured variables, according to an example embodiment of the present invention.

FIG. 6 shows in a graph an exemplary current pulse of a DC converter.

FIG. 7 shows in a flowchart one possible check of the internal resistance of a battery in the vehicle electrical system, according to an example embodiment of the present invention.

FIG. 8 shows the plausibility check of the calculation of the internal resistance of the battery, according to an example embodiment of the present invention.

### DETAILED DESCRIPTION OF EXAMPLE EMBODIMENT

The present invention is schematically represented in the drawings based on specific embodiments and is described in greater detail below with reference to the figures.

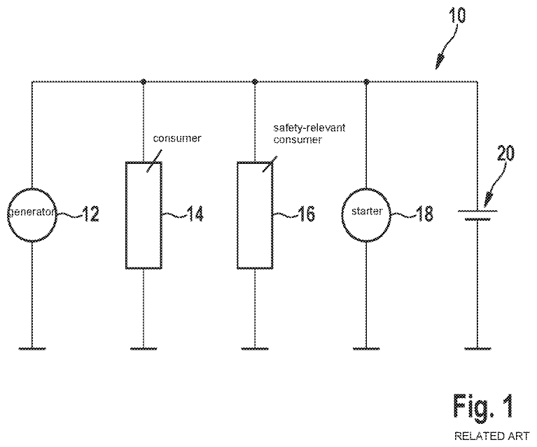

An exemplary 12 Volt vehicle electric power system of a vehicle for manual driving is represented in FIG. 1, which is identified in its entirety by reference numeral 10. The representation shows as components of vehicle electrical system 10 a generator 12, a 12V consumer R_{B, 12V} 14, a safety-relevant consumer R_{SR} 16, a starter S 18 and a 12V battery 20.

It should be noted that, for example, in today's vehicle electrical power systems an ASIL B is allocated to the supply of the safety-relevant consumers. This results in a safe power supply from battery 20 with ASIL B.

In this case, it should be considered, however, that the safety requirements for the power supply in the vehicle increase constantly. The reasons for this are in the case of manual driving, for example, heavier vehicles, for example, BEV (battery electrical vehicle) including 800 kg batteries, in which a total weight of more than 3 t is possible, or the trend toward larger vehicles and the associated poorer controllability of the vehicle if steering support is lost. To implement the braking support or steering support, electrical power from the vehicle electrical power system is required, as a result of which the requirements of the electrical power supply increase, for example, to ASIL C.

In order to be able to ensure the high safety requirements of the power supply, a particular battery and its associated monitoring, among other things, are employed in the safety concept. To monitor the performance capacity or performance of the battery, internal resistance Rᵢ of battery 20, for example, is determined. With monitored battery 20, it is ensured that the remaining risk, for example, during manual or automated driving remains below an allowable residual risk due to a failure of the vehicle electrical power system.

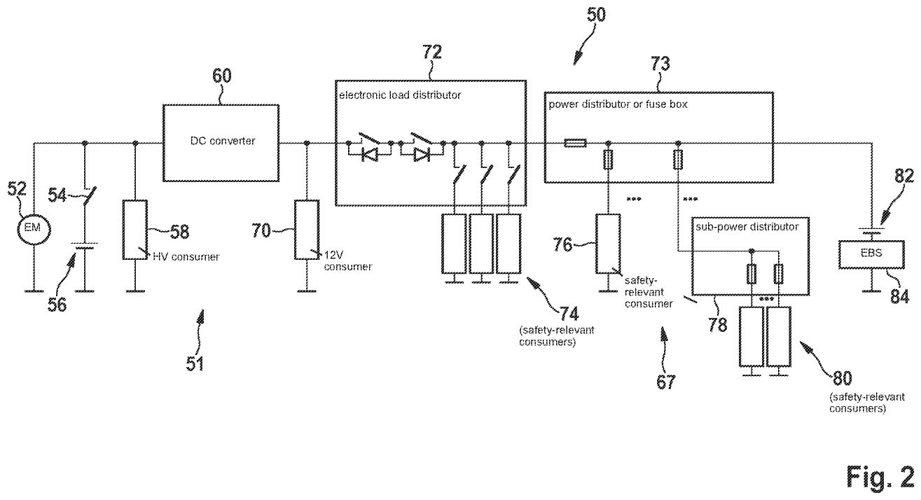

To be able to ensure the safe power supply of the safety-relevant consumers, in FIG. 1, consumer 16, for example with ASIL C, the use of an EBS is no longer sufficient, since the EBS is able to be developed optionally systematically maximally according to ASIL B or the required hardware metrics with an EBS alone are not achieved. To be able to ensure the energy supply of the battery according to ASIL C, an embodiment of a vehicle electrical system according to FIG. 2 is therefore presented.

FIG. 2 shows a vehicle electrical system, which is identified in its entirety by reference numeral 50. This vehicle electrical system 50 includes on one side having a higher voltage level 51 an electric machine EM 52, a high-volt/48V battery B_{HV/48V} 56, a HV/48V consumer R_{B,HV/48V} 58 and a DC converter 60. In lithium-ion batteries, a switch 54 is integrated for avoiding overcurrents and thus for thermal self-protection. A side having low voltage level 67 is provided with a 12V consumer R_{B,12V} 70, representative of the plurality of 12V non-safety-relevant consumers (NSRV), an electronic load distributor 72, a conventional power distributor or a fuse box 73, safety-relevant consumers 74, safety relevant consumers 76, a sub-power distributor 78, safety-relevant/post crash/NSRV consumer 80, a battery B₁ 82 and a sensor for monitoring 84 assigned to battery B₁ 82.

Thus, in this embodiment, the battery monitoring with ASIL C is carried out with the aid of EBS 84 in combination with intelligent load distributor (IELV) 72. Difficulties arise, however, when monitoring EBS 84 by IELV 72 in the presented vehicle electrical system 50, which is also referred to here as a vehicle electrical power system, in that an unknown current discharge takes place between battery 82 and IELV 72.

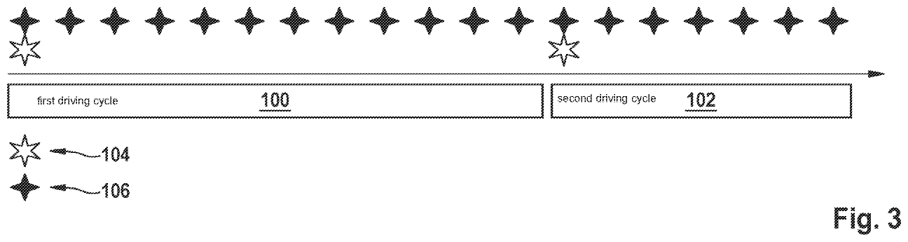

To monitor battery 82, internal resistance Rᵢ of battery 82, among other things, is ascertained. EBS 84 is used in vehicle electrical system 50 for this purpose. Since EBS 84 does not achieve the systematic safety integrity, for example, ASIL C, and/or the required hardware metrics, a plausibility check is carried out via intelligent IELV 72. Due to unknown discharges between the relevant IELV measuring points and battery 82, this is not trivial. For this reason, a two-stage concept is used, which is addressed in FIG. 3.

Alternatively, the method may also be used in vehicle electrical systems with only one voltage level, for example, 12V.

FIG. 3 shows an exemplary implementation of a first driving cycle 100 and of a second driving cycle 102. A first symbol 104 shows a plausibility check of the EBS measured values, a second symbol 106 shows a plausibility check of the calculation of internal resistance Rᵢ of the battery.

In a first step, the accuracy of the measurements of the EBS is checked. In the process, the plausibility of the measured values is checked, which are relevant for the Rᵢ determination. This plausibility check is carried out once per driving cycle.

In a second step, the correct calculation of the Rᵢ is checked by the EBS. This control of the EBS calculation is carried out repeatedly in the driving cycle in order to be able to recognize errors in the EBS in a timely manner before violating the safety target.

Thus, a two-stage method is provided, both stages of which are addressed in greater detail below:

In stage 1, the plausibility check of the measured values of the EBS is carried out. To calculate internal resistance Rᵢ of the battery, the following measured values, among other things, are required.

current measurement, relevant in this case is mainly the current jump, the offset may be disregarded,
voltage measurement, relevant in this case is mainly the voltage jump, the offset may be disregarded.

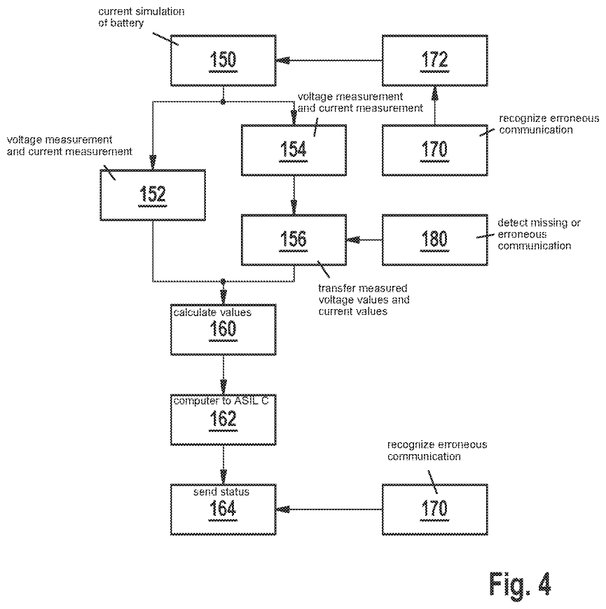

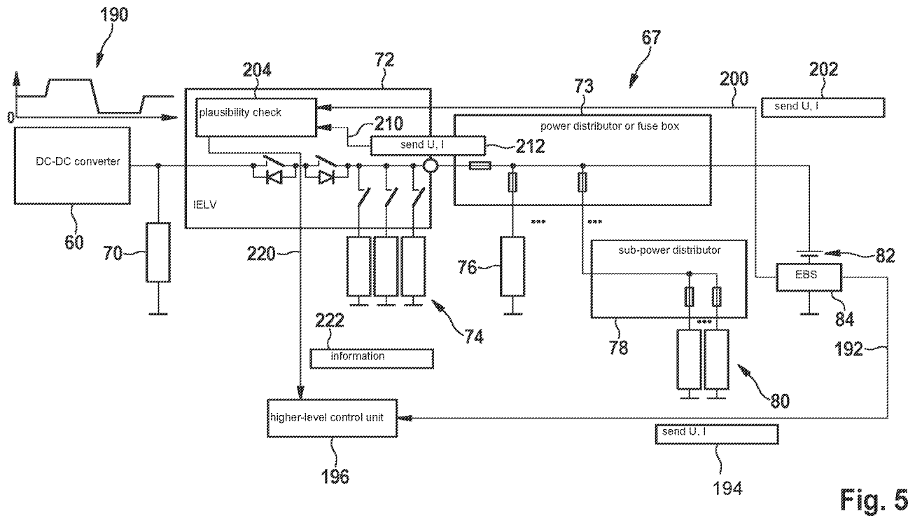

It should be noted that erroneous measurements of the EBS with respect to current drift and voltage drift should be recognized by the plausibility check. The process according to FIG. 4 and the signal flow according to FIG. 5 are provided for this purpose.

FIG. 4 shows in a flowchart one possible sequence of the plausibility check of the EBS measured variables. In a first step 150, a current simulation of the battery takes place, for example, by the DC-DC converter. This is followed in a second step 152 by a voltage measurement and current measurement by electronic load distributor (IELV) 154 according to ASIL A(C). A voltage measurement and current measurement by the EBS according to ASIL B(C) takes place in parallel thereto in a step 154, and then a transfer of the measured voltage values and current values to the IELV with ASIL B(C) takes place in a step 156.

The IELV subsequently calculates in a step 160 the values for ΔU_{EBS}, ΔI_{EBS}, and ΔU_{IELV}, ΔI_{IELV} according to ASIL C. The IELV then compares ΔU_{EBS}, ΔI_{EBS}, and ΔU_{IELV}, ΔI_{IELV} according to ASIL C in a step 162. If the difference of the values of EBS and IELV exceed a threshold value, then a status error is assumed. The IELV then sends in a step 164 the status to an ECU at a higher level with ASIL C. An erroneous communication must be avoided with ASIL C.

An erroneous communication of the IELV must be recognized in a parallel step 170 by an ECU at a higher level with ASIL C. In the IELV, the regular excitations, which are a prerequisite for the battery status recognition, must also be monitored according to ASIL C and a communication to an ECU at a higher level with ASIL C takes place in the event of an erroneous excitation. An ECU at a higher level generates a measure, for example, a trigger excitation or a transition into a safe state.

In addition, a detection by the IELV of a missing or erroneous communication of the EBS according to ASIL C takes place in a step 180.

FIG. 5 shows the side having low voltage level 67 from FIG. 2 including the signal flows for illustrating the plausibility check of the measured values. The representation shows coupled DC-DC converter 60, 12V consumer R_{B,12V} 70, electronic load distributor (IELV) 72, the conventional power distributor or fuse box 73, safety-relevant consumers 74, safety-relevant consumer 76, power distributor 78, safety-relevant/post-crash/NSRV consumer 80, battery B₁ 82 and EBS 84 assigned to battery B₁ 82. A graph 190 illustrates a current signal, which is predefined by the DC-DC converter.

The signal flows are addressed in greater detail below, the numbering not being intended to establish any temporal sequence. A first signal flow 192 sends as information 194, U, I according to ASIL B(C) from EBS 84 to a higher-level control unit 196, for example, to an electronic energy management (EEM). A second signal flow 200 sends as information 202 U, I with ASIL B(C) from EBS 84 to IELV 72, in which a plausibility check 204 of U, I according to ASIL C takes place. A third signal flow 210 sends as information 212 U, I according to ASIL A(C) to plausibility check 204 in IELV 72. Current values are typically ascertained from main switch/secondary switch measuring points, the voltage is typically ascertained at one point in the IELV. From plausibility check 204, a fourth signal flow 220 with information 222 whether the values are plausible takes place to higher-level control unit 196.

FIG. 6 shows an exemplary current pulse of the DC-DC converter in a graph 250, at abscissa 252 of which time t is plotted and at ordinate 254 of which current I is plotted.

To be able to monitor the state of the battery, a certain excitation, for example, in the form of a current peak, is required. Depending on the operating strategy and vehicle use, these excitations occur very rarely in the vehicle electrical system, for which reason it is not possible to fully monitor the state of the battery. To close these diagnostic gaps, the vehicle electrical power system is actively stimulated. This is possible, for example, using the DC-DC converter, which applies, for example, a current square pulse according to FIG. 6 to the vehicle electrical power system for a defined duration of a defined current pulse. The IELV must ensure with ASIL C that the excitation occurs with sufficient frequency, otherwise must report to the higher-level control unit, i.e. accuracy of the message ASIL C, monitoring of the communication by higher-level control unit with ASIL C.

The excitation may also be differently achieved, for example, by switching on and off high load consumers.

The EBS sends its ASIL B(C) raw signals U_{EBS}, I_{EBS}, T_{EBS} to the intelligent electrical power distributor. The electric power distributor measures U_{IELV}, I_{IELV}, T_{IELV} at particular operating points, i.e., when carrying out a test pulse, as is described above, in ASIL A(C) quality. In the intelligent electronic load distributor, delta variables are ascertained and the delta variables of the EBS are compared with the delta variables of the IELV, with ASIL C integrity. In this way, it may be established whether the measurement of the EBS is error-free and the measuring signals of the EBS are raised as a result to ASIL C integrity.

Alternatively, the EBS already sends delta values to the IELV. The IELV itself ascertains the delta values and compares these.

When comparing the measured values, the current at the outgoing conventional power distributor should be taken into account as the relevant interference variable, see FIG. 2, since this current is unable to be directly measured. When comparing the current deltas and voltage deltas on the IELV side and EBS side, an existing constant current through the conventional distributor is eliminated by the delta calculation. Load fluctuations present merely at the point in time of the test pulse interfere with the comparison. To eliminate the influence of such interferences to the extent possible, the following measures may be taken:

carrying out the test during an initialization phase or in the follow-up movement of the vehicle, in order to reduce the number of active systems or actuators to a minimum.
generating a test signal, in which multiple edges are evaluatable. Randomly occurring switching edges on the part of the conventional load distributor do not equally affect all edges, thus, when comparing multiple edges in succession and when applying a 1 from N selection, it is possible to filter the interference.
if the measured data of a test are not consistent, the test may be repeated multiple times in order to increase the reliability of the conclusion.
the interference resulting from a load edge on the conventional load distributors may result in erroneously recognized defects in the measuring chain, which causes a transition into the safe state. This means, the system is basically safe, a misdiagnosis results merely in a reduction of the availability.

The IELV sends to the higher-level control unit 196 the information that EBS 84 is measuring correctly. Alternatively, it may be provided in a simpler embodiment: a measurement of the previously unknown current discharges through additional measuring points or a measurement of the battery current takes place.

The measurement of the physical variables in the IELV may be calculated in this case directly at the connection of the battery path in the IELV or by calculation according to node and mesh rules in the IELV. In addition, sense lines or the like may be provided with direct measurement at the battery.

The plausibility check of the measured variables of the EBS presented herein ensures that the signals necessary for the assessment of the battery performance capacity are present in ASIL C quality.

Stage 2 is addressed below, in which a plausibility check of the EBS performance variables takes place.

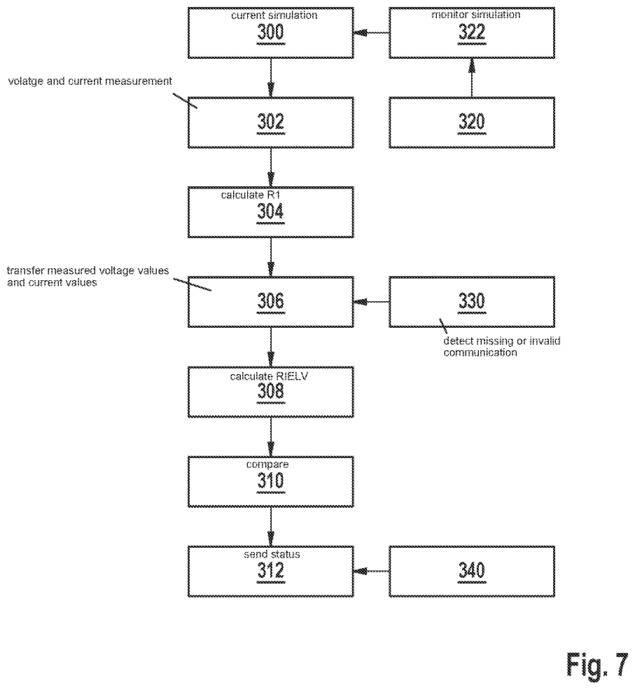

For this purpose, FIG. 7 shows in a flowchart a sequence for checking the accuracy of internal resistance Rᵢ of the battery. In a first step 300, a current excitation of the battery takes place via the DC-DC converter. In a subsequent step 320, a voltage measurement and current measurement by the EBS according to ASIL B(C) takes place. The EBS then calculates in a step 304 the Rᵢ with ASIL B(C). In a step 306, a transfer of measured voltage values and current values and R_{IEBS} to the IELV according to ASIL B(C) then takes place. In a step 308, the IELV calculates R_{IELV} based on the EBS voltage measurement and EBS current measurement according to ASIL A(C). In a step 310, the IELV subsequently compares R_{IEBS} and R_{IELV}. The IELV then sends in a step 312 a status to an ECU at a higher level with ASIL C. An erroneous communication must be avoided with ASIL C.

In addition, a detection of a missing or erroneous communication to an ECU at a higher level with ASIL C takes place. In a step 322, the IELV monitors a sufficiently frequent excitation with ASIL C, a communication to an ECU at a higher level with ASIL C takes place in the case of a lacking excitation. A measure of a higher-level ECU, for example, a triggering of an excitation or a transition into the safe state, takes place.

In addition, the IELV detects in a step 330 a missing or invalid communication of the EBS with ASIL C.

It should be noted that Rᵢ should be ascertained in short time intervals in order, for example, to be able to recognize cell short circuits. The sequence of this plausibility check is represented in FIG. 7. A sufficient excitation in the vehicle electrical system or in the vehicle electrical power system is also required for the Rᵢ determination. The excitation may be carried out as is described above. The EBS ascertains current and voltage profiles and calculates the Rᵢ. The EBS sends both raw data as well as the calculated R_{IEBS} to the IELV.

Since the transfer rate of the bus system, for example, of a LIN, is very limited, the data in the EBS are sent as a packet. The LIN communication is not able to transfer all measured data in real time. The EBS includes for this purpose a recognition mechanism, which recognizes that a current edge occurs. The EBS thereupon stores the required current and voltage values; if necessary, a filtering of the values takes place. Independently thereof, the EBS permanently calculates the Rᵢ. The data as well as the R_{IEBS} are subsequently sent as data packets. Alternatively, each individual measured value may also be sent, for example, via a different communication interface.

The IELV calculates the R_{IELV} and thus ascertains whether the EBS has calculated correctly. The IELV sends the status whether Rᵢ is in order to a higher-level control unit, for example, to an energy management.

Multiple excitation edges are necessary in order to be able to carry out an accurate Rᵢ determination. These excitation edges are sent to the IELV and evaluated. To achieve a diverse redundancy, different algorithms may be used in the EBS and/or IELV for determining the Rᵢ. Alternatively, the algorithm may be developed according to ASIL C.

It should be noted that the method presented may, in principle, also be used for other ASIL classifications.

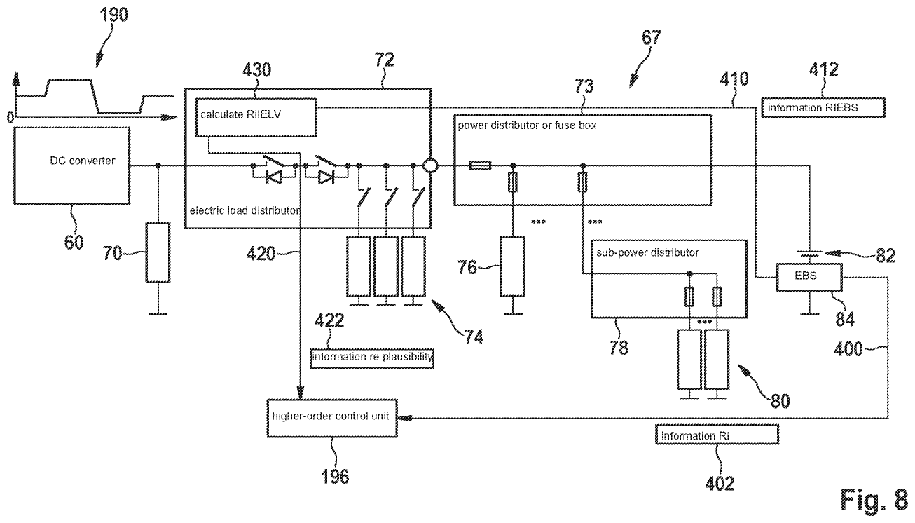

FIG. 8 shows the low voltage side from FIG. 5 for illustrating the plausibility check of the Rᵢ calculation. A first signal flow 400 carries as information 402 Rᵢ according to ASIL B(C). A second signal flow 410 carries as information 412 R_{IEBS}; U, I according to ASIL B(C). A third signal flow 420 carries as information 422 an indication of whether the values are plausible. In IELV 72, a calculation of R_{iIELV} on the basis of U, I and a plausibility check of R_{iIEBS} and R_{iIELV} according to ASIL C take place in 430.

It should be noted that the method is easier to carry out if no further load distributor is situated between the battery and the IELV. Rᵢ may then be directly carried out in the IELV, i.e., a measurement directly in the IELV with ASIL C, since the LIN communication is omitted. The same applies to the selection of a different communication system with higher data transfers and, optionally real time capability. In addition, the EBS may be connected directly at the IELV, the EBS may also communicate with the IELV via a different control unit, for example, a gateway.

1-13. (canceled)

14. A method for operating a vehicle electrical system, which includes an energy store, a sensor processing unit assigned to the energy store, and an electronic load distributor, at least one measured variable of the energy store being detected using the sensor processing unit and a parameter of the energy store being calculated taking the at least one measured variable into account, the method comprising:
in a first step, checking a plausibility check of the at least one measured variable, using the electronic load distributor; and
in a second step, checking a plausibility check of the calculation using the electronic load distributor.

15. The method as recited in claim 14, wherein the plausibility check of the at least one measured variable in the first step is carried out once per driving cycle and the plausibility check of the calculation in the second step is carried out multiple times in the driving cycle.

16. The method as recited in claim 14, wherein the energy store is a battery, to which an electronic battery sensor as the sensor processing unit is assigned.

17. The method as recited in claim 16, wherein a current and a voltage are detected as measured variables of the at least one measured variable and an internal resistance of the battery is calculated as the parameter.

18. The method as recited in claim 17, wherein a current jump and a voltage jump are detected as measured variables of the at least one measured variable.

19. The method as recited in claim 18, wherein multiple excitation edges are used for calculating the internal resistance of the battery.

20. The method as recited in claim 14, wherein the method is carried out during an initialization phase.

21. The method as recited in claim 14, wherein which is carried out in a follow-up movement of a vehicle.

22. The method as recited in claim 14, wherein a test signal is predefined for carrying out the method.

23. The method as recited in claim 14, in which results of the plausibility check of the at least one measured variable in the first step and the plausibility check of the calculation in the second step are forwarded to a higher-level processing unit.

24. A vehicle electrical system, comprising:
an energy store;
an sensor processing unit assigned to the energy store; and
an electronic load distributor;
wherein, in the vehicle electrical system, at least one measured variable of the energy store is detected using the sensor processing unit and a parameter of the energy store is calculated taking the at least one measured variable into account, and
wherein the vehicle electrical system is configured to:
perform a plausibility check of the at least one measured variable, using the electronic load distributor; and
perform a plausibility check of the calculation using the electronic load distributor.

25. The vehicle electrical system as recited in claim 24, wherein the vehicle electrical system has a side having a higher voltage level and a side having a lower voltage level, the energy store and the electronic load distributor being provided on the side having the lower voltage level.

26. The vehicle electrical system as recited in claim 24, wherein the energy store is a battery, and the sensor processing unit is an electronic battery sensor.
